(19) United States
(12) Patent Application Publication
(10) Pub. No.: US 2012/0326314 A1
(43) Pub. Date: Dec. 27, 2012

(54) LARGE-GRAIN, LOW-RESISTIVITY TUNGSTEN ON A CONDUCTIVE COMPOUND

(75) Inventors: Stephen L. Brown, Yorktown Heights, NY (US); John Bruley, Yorktown Heights, NY (US); Cyril Cabral, JR., Mahopac, NY (US); Sandro Callegari, Yorktown Heights, NY (US); Martin M. Frank, Dobbs Ferry, NY (US); Michael A. Guillorn, Yorktown Heights, NY (US); Marinus Hopstaken, Yorktown Heights, NY (US); Vijay Narayanan, New York, NY (US); Keith Kwong Hon Wong, Wappingers Falls, NY (US)

(73) Assignee: INTERNATIONAL BUSINESS MACHINES CORPORATION, Armonk, NY (US)

(21) Appl. No.: 13/604,959

(22) Filed: Sep. 6, 2012

Related U.S. Application Data
(63) Continuation of application No. 13/042,618, filed on Mar. 8, 2011.

(51) Int. Cl. H01L 23/48; H01L 21/28

(52) U.S. Cl. 257/761; 438/608; 257/E23.01; 257/E21.158

(57) ABSTRACT

A layered structure and semiconductor device and methods for fabricating a layered structure and semiconductor device. The layered structure includes: a base layer including a material containing titanium nitride, tantalum nitride, or a combination thereof; a conductive layer including a material containing: tantalum aluminum nitride, titanium aluminum nitride, tantalum silicon nitride, titanium silicon nitride, tantalum hafnium nitride, titanium hafnium nitride, hafnium nitride, hafnium carbide, tantalum carbide, vanadium nitride, niobium nitride, or any combination thereof; and a tungsten layer. The semiconductor device includes: a semiconductor substrate; a base layer; a conductive layer; and a tungsten layer.

### CROSS REFERENCE TO RELATED APPLICATIONS

The present application is a continuation of and claims priority to U.S. patent application Ser. No. 13/042,618, filed Mar. 8, 2011, the contents of which are incorporated by reference in its entirety.

### BACKGROUND

The present invention relates generally to semiconductor and microelectronics structures and methods for fabricating these structures. More particularly, the invention relates to semiconductor and microelectronics devices, and methods for fabricating these devices, where the device includes a conductive compound as an underlayer that allows for a tungsten deposit to form large grain size and resulting in low resistivity.

### DESCRIPTION OF THE RELATED ART

Tungsten is a metallization element with multiple uses in electronics, and in particular in chip technology. Examples of such uses include but are not limited to using the tungsten plug fill process for filling contacts and vias in front- and back-end metallization, using tungsten as an interconnect material, using tungsten as a component of the metal-oxide-semiconductor field-effect transistor (MOSFET) gate stack, and using tungsten as a component of the dynamic random access memory (DRAM) gate stack.

In most cases, minimum resistivity of tungsten is desirable for optimum circuit performance. Since grain boundary scattering of electrons in tungsten is one of the main factors limiting electrical conductivity (i.e., increasing resistivity), large tungsten grain size is therefore desirable for many applications.

Often, tungsten is deposited onto titanium nitride (TiN) or tantalum nitride (TaN), e.g., as a barrier material in contact/via/interconnect technology, or as a metal gate material in direct contact with a high-permittivity (‘high-K’) dielectric in MOSFET gate stack technology. FIG. 1a shows a cross sectional view of a semiconductor device 100 with a semiconductor substrate 110 and a gate stack 105 that has a titanium nitride (TiN) or tantalum nitride (TaN) layer 115 as the underlayer for a tungsten deposit 120. FIG. 1b shows an example of such a device. In this example semiconductor device 150, a silicon layer 160 is used as a semiconductor substrate. Optional layers are included in the gate stack 155, such as the silicon dioxide (SiO₂) interfacial layer 165 which overlays the silicon substrate 160, the hafnium (HO-based high-K gate dielectric layer 170 which overlays the SiO₂ interfacial layer 165, and the silicon nitride (Si₃N₄) encapsulation layer 185 which overlays the tungsten layer 180.

In existing technology, when depositing tungsten onto TiN or TaN, small-grain, high-resistivity tungsten is often formed. Grain size can be increased and resistivity can be reduced, via special treatments before and during tungsten deposition and via multi-step deposition procedures. However, such procedures may reduce manufacturing throughput and increase cost.

### SUMMARY OF THE INVENTION

According to one aspect of the present invention, a layered structure is provided that includes: a base layer including a material containing: titanium nitride (TiN), tantalum nitride (TaN), or a combination thereof; a conductive layer overlaying the base layer, where the conductive layer includes a material containing: tantalum aluminum nitride (TaAlN), titanium aluminum nitride (TiAlN), tantalum silicon nitride (TaSiN), titanium silicon nitride (TiSiN), tantalum hafnium nitride (TaHfN), titanium hafnium nitride (TiHfN), hafnium nitride (HfN), hafnium carbide (HfC), tantalum carbide (TaC), vanadium nitride (VN), niobium nitride (NbN), or any combination thereof; and a tungsten layer deposited above the conductive layer.

According to another aspect of the present invention, a semiconductor device is provided that includes: a semiconductor substrate; a base layer including a material containing: TiN, TaN, or a combination thereof; a conductive layer overlaying the base layer, where the conductive layer includes a material containing: TaAlN, TiAlN, TaSiN, TiSiN, TaHfN, TiHfN, HfN, HfC, TaC, VN, NbN, or any combination thereof; and a tungsten layer deposited above the conductive layer.

According to yet another aspect of the present invention, a method is provided for fabricating a layered structure. The method includes: depositing a conductive layer on a base layer, where the conductive layer includes a material containing: TaAlN, TiAlN, TaSiN, TiSiN, TaHfN, TiHfN, HfN, HfC, TaC, VN, NbN, or any combination thereof, and where the base layer has a material containing: TiN, TaN, or a combination thereof; and depositing a tungsten layer above the conductive layer.

According to still another aspect of the present invention, a method is provided for fabricating a semiconductor device. The method includes: depositing a base layer on a semiconductor substrate, where the base layer has a material containing: TiN, TaN, or a combination thereof; depositing a conductive layer on the base layer, where the conductive layer includes a material containing: TaAlN, TiAlN, TaSiN, TiSiN, TaHfN, TiHfN, HfN, HfC, TaC, VN, NbN, or any combination thereof; and depositing a tungsten layer above the conductive layer.

### BRIEF DESCRIPTION OF THE SEVERAL VIEWS OF THE DRAWINGS

FIG. 1a is a cross sectional view of a semiconductor device with a gate stack that has a titanium nitride (TiN) or tantalum nitride (TaN) layer as the underlayer for a tungsten deposit.

FIG. 1b is a cross sectional view of an example semiconductor device of FIG. 1a.

FIG. 2a is a cross sectional view of a semiconductor device with a gate stack that has a conductive layer as the underlayer for a tungsten deposit according to an embodiment of the present invention. The conductive layer does not contain or is not entirely made of TiN, TaN, or a combination of TiN and TaN.

FIG. 2b is a cross sectional view of a sample semiconductor device of FIG. 2a.

FIG. 3 is a cross sectional view of another semiconductor device according to an embodiment of the present invention.

FIG. 4a is a cross sectional view of a layered structure having a conductive layer as the underlayer for a tungsten deposit according to an embodiment of the present invention. The conductive layer does not contain or is not entirely made of TiN, TaN, or a combination of TiN and TaN.

FIG. 4b is a cross sectional view of an example layered structure of FIG. 4a.

FIG. 5 is a flow chart illustrating an overview of a method of fabricating a semiconductor device with a gate stack having a conductive layer as an underlayer for a tungsten deposit according to an embodiment of the present invention. The conductive layer does not contain or is not entirely made of TiN, TaN, or a combination of TiN and TaN.

FIG. 6 is a flow chart illustrating an overview of a method of fabricating a layered structure with a conductive layer as an underlayer for a tungsten deposit according to an embodiment of the present invention. The conductive layer does not contain or is not entirely made of TiN, TaN, or a combination of TiN and TaN.

### DETAILED DESCRIPTION OF PREFERRED EMBODIMENTS

It will be readily understood that the components of the present invention, as generally described and illustrated in the figures herein, may be arranged and designed in a wide variety of different configurations in addition to the described presently preferred embodiments. Thus, the following detailed description of the embodiments of the present invention, as represented in the figures, is not intended to limit the scope of the invention, as claimed, but is merely representative of selected presently preferred embodiments of the invention. The following description is intended only by way of example, and simply illustrates certain selected presently preferred embodiments of the invention as claimed herein.

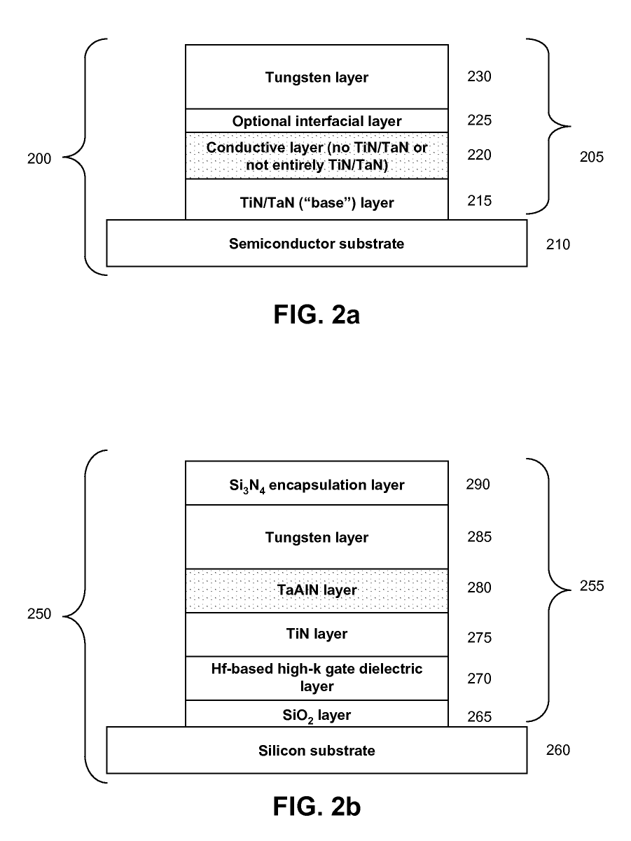

According to one embodiment of the present invention, a semiconductor device has a gate stack that includes an underlayer for a tungsten deposit. This underlayer can be a conductive layer that does not contain or is not entirely made of titanium nitride (TiN), tantalum nitride (TaN), or a combination of TiN and TaN. The underlayer can also be a combination of an interfacial layer that overlays the conductive layer. Referring to FIG. 2a, the illustration shows a cross sectional view of such a semiconductor device 200.

The semiconductor device 200 has a semiconductor substrate 210 and a gate stack 205 that includes: a “base” layer which contains TiN, TaN, or a combination of TiN and TaN 215, a conductive layer that does not contain or is not entirely made of TiN, TaN, or a combination of TiN and TaN 220, and a tungsten layer 230. The gate stack 205 can also include other optional layers such as an interfacial layer 225 between the conductive layer 220 and the tungsten layer 230.

The semiconductor material making up the semiconductor substrate 210 can be any semiconductor material, either doped or undoped, including but not limited to silicon, silicon germanium, germanium, silicon carbide, a III-V compound semiconductor, a II-VI compound semiconductor, a carbon-based semiconductor such as a carbon nanotube or graphene, an organic semiconductor, or any multilayer or other combination of these. The present invention has applicability to both semiconductor-on-insulator (e.g. silicon-on-insulator, SOI) and bulk semiconductor technology.

A first optional interfacial layer (not shown in the figure) can be formed on the semiconductor substrate 210. This interfacial layer can be made of an oxide, nitride, or oxynitride of the semiconductor substrate 210, for example silicon dioxide (SiO₂), silicon nitride (Si3N4), or silicon oxynitride (SiON), or it can be made of any other insulating material. It can measure roughly less than 100 Angstrom, and preferably less than 15 Angstrom, in thickness. Techniques for forming the first optional interfacial layer include, but are not limited to, exposure to gases, liquids, or plasmas, at room temperature or at elevated temperature, either before or after the addition of the gate stack 205.

An optional gate dielectric layer (not shown in the figure) can be deposited onto the semiconductor substrate 210 or it can be deposited onto the first optional interfacial layer. High-K dielectric materials can be used for this gate dielectric layer—i.e., a dielectric layer with a higher dielectric constant than SiO₂ including at least one metallic element, such as hafnium oxide (HfO₂), zirconium oxide (ZrO₂), aluminum oxide (Al₂O₃), hafnium silicate (HfSiO), nitrided hafnium silicate (HfSiON), hafnium oxynitride (HfOₓN_{y}), lanthanum oxide (La₂O₃), lanthanum aluminate (LaAlO₃), zirconium silicate (ZrSiOₓ), and any other dielectric material having a dielectric constant higher than that of SiO₂ (the dielectric constant of SiO₂ is 3.9). If a high-K dielectric material is used, the high-K gate dielectric layer can be made of two or more sublayers. The gate dielectric layer should have an approximate thickness of 10 to 1000 Angstrom, and more preferably 10 to 40 Angstrom. If the gate dielectric layer is an oxide, nitride, or oxynitride, of the semiconductor substrate 210, such as SiO₂ or SiON, the thickness of the gate dielectric layer would include the thickness of the first optional interfacial layer, if this interfacial layer 215 has been formed.

The base layer 215 can be deposited onto the semiconductor substrate 210 or it can be deposited onto the first optional interfacial layer if it exists or the optional gate dielectric layer if it exists. In its as-deposited state, the base layer 215 is composed substantially of titanium and nitrogen and/or tantalum and nitrogen, respectively, but may optionally also include smaller amounts of other elements, where the amount of other non-metal elements such as for example oxygen, carbon, boron, or hydrogen, preferably is lower than about 20 atom percent, and the amount of other metal elements such as for example hafnium, aluminium, or lanthanum is lower than about 5 atom percent. The base layer 215 preferably measures approximately 10 to 1000 Angstrom, and more preferably 10 to 200 Angstrom, in thickness.

The conductive layer 220 can be deposited onto the base layer 215. The conductive layer 225 includes a material containing: tantalum aluminum nitride (TaAlN), titanium aluminum nitride (TiAlN), tantalum silicon nitride (TaSiN), titanium silicon nitride (TiSiN), tantalum hafnium nitride (TaHfN), titanium hafnium nitride (TiHfN), hafnium nitride (HfN), hafnium carbide (HfC), tantalum carbide (TaC), vanadium nitride (VN), niobium nitride (NbN), or any combination thereof. The conductive layer 225 can be substantially made of the above-described materials or any of these materials additionally including smaller amounts of other elements, where the amount of other elements preferably is lower than about 20 atom percent. Alternatively, the conductive layer 225 can in its as-deposited state be substantially made of any other conductive material that is not entirely made of TiN, TaN, or a combination not TiN and TaN and that, optionally combined with the optional interfacial layer 225, allows the tungsten layer 230 to form large grains, resulting in low resistivity. The conductive layer measures about 10 to 1000 Angstrom, and preferably about 10 to 200 Angstrom, in thickness.

If the conductive layer 220 is made of TaAlN or TiAlN, then the conductive layer 220 should contain a sufficient aluminum content and appropriate nitrogen content to allow the tungsten layer 230 to form large grains, resulting in low resistivity. A sufficient aluminum content can be between about 5 and 40 atom % and preferably between about 10 and 35 atom %. An appropriate nitrogen content can be between about 10 and 50 atom %. For example, the conductive layer 220 can contain approximately 16% Al and approximately 30% N. If the conductive layer 220 is made of TaAlN or TiAlN and it contains a low aluminum content of approximately less than 15 atom %, it is particularly preferred for a surface oxidation process to be performed (to be discussed below.) The surface oxidation process can also be optionally performed if the conductive layer 220 contains a higher aluminum content. If the conductive layer 220 is made of other materials, then the conductive layer 220 or the semiconductor device 200 can also be optionally subject to surface oxidation.

The optional interfacial layer 225 that is between the conductive layer 220 and the tungsten layer 230 can be deposited onto the conductive layer 225. This second optional interfacial layer 225 can be made, for example, of Al₂O₃, HfO₂, or SiO₂, or of any material that allows the tungsten layer 230 to form large grains, resulting in low resistivity. The second optional interfacial layer 225 should measure approximately 1 to 20 Angstrom, and preferably approximately 1 to 10 Angstrom, in thickness.

The tungsten layer 230 can be deposited onto the conductive layer 220 or the optional interfacial layer 225. The tungsten layer can optionally also contain smaller amounts of other elements, either immediately after tungsten deposition or after device fabrication, where the amount of other elements such as for example nitrogen, oxygen, titanium, or tantalum, or of any other element, preferably is lower than about 10 atom percent. The tungsten layer may have any thickness. For most applications, it should measure approximately 10 to 1000 Angstrom, and preferably approximately 50 to 500 Angstrom, in thickness.

An optional encapsulation layer (not shown in the figure) can be deposited onto the tungsten layer 230. The encapsulation layer can be made of any material. For many applications, it is preferable for the optional encapsulation layer to be made of an insulating compound such as silicon nitride (Si₃N₄), Al₂O₃, HfO₂, or ZrO₂ and for it to measure approximately 10 to 500 Angstrom in thickness. The encapsulation layer can be partially or completely removed subsequently in processing, for example to make contact to the gate line.

Referring to FIG. 2b, the illustration shows a cross sectional view of a sample semiconductor device 250 of FIG. 2a. In this sample semiconductor device 250, a silicon layer 260 is used as a semiconductor substrate. In the gate stack 255, the following layers are present in the order indicated:

an interfacial layer made of SiO₂ 265, which measures 5 to 10 Angstrom in thickness, overlays the silicon substrate 260;

a hafnium silicon oxynitride (HfSiON) high-K gate dielectric layer 270, which measures 20 Angstrom in thickness, overlays the SiO₂ layer 265;

a TiN layer 275, which measures 75 Angstrom in thickness, overlays the Hf-based high-K gate dielectric layer 270;

a conductive layer 280, which is made of TaAlN and measures 100 Angstrom in thickness overlays the TiN layer 275;

a tungsten layer 285, which measures 125 Angstrom in thickness, overlays the conductive layer 280; and

a Si₃N₄ encapsulation layer, which measures 200 Angstrom in thickness overlays the tungsten layer 285.

The TaAlN conductive layer 280 is composed of approximately 38 atom % Ta, 30 atom % Al, and 32 atom % N.

After the TaAlN conductive layer 280 was deposited, the device 250 was subjected to air exposure to introduce oxygen atoms.

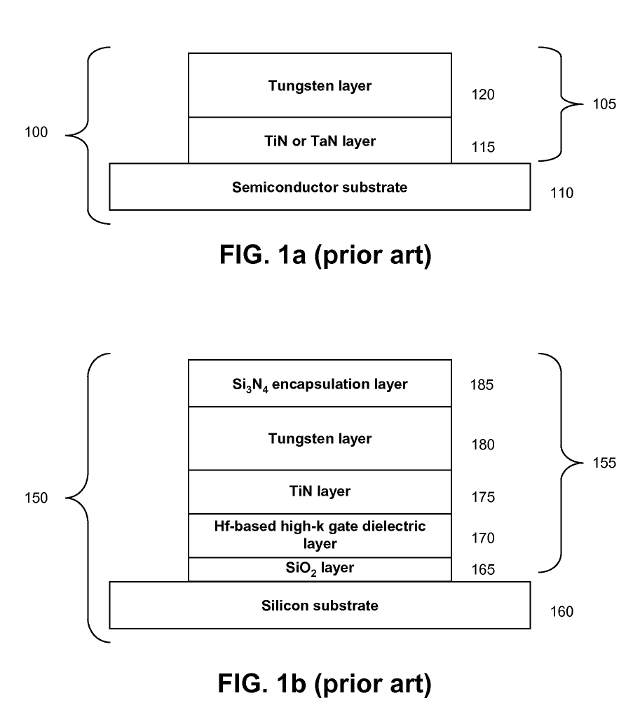

The TaAlN conductive layer 280, when used as an underlayer for the tungsten layer 285, allowed for the formation of much larger tungsten grains, many of them greater than 40 nanometers wide after processing of the device was completed, compared to the case where the TiN layer 175 (FIG. 1b) was used as an underlayer, in which most tungsten grains measured at less than 10 nanometers wide.

Due to little grain boundary scattering, the sheet resistance of the tungsten layer 285 was measured to be lower, at approximately 9.6 Ohm/square, corresponding to a desirable resistivity of about 12 microOhm cm, compared to that of the tungsten layer 180 (FIG. 1b) which was deposited on the TiN layer 175 (FIG. 1b.) The sheet resistance of the tungsten layer 180 measured at approximately 38.8 Ohm/square, corresponding to a less desirable resistivity of about 48.5 microOhm cm. While these values were measured after full device processing, even right after tungsten deposition the tungsten layer 285 had low sheet resistance of 11 to 13 Ohm/square, corresponding to a resistivity of about 13.75 to 16.25 microOhm cm.

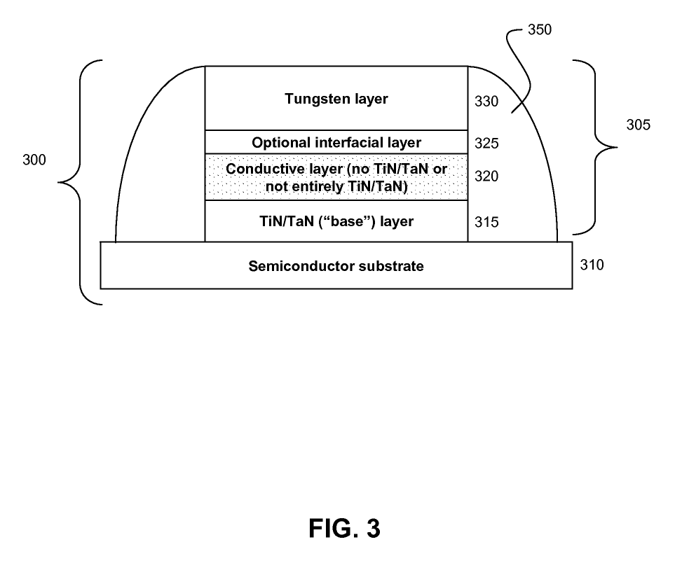

Referring to FIG. 3, the illustration shows a cross sectional view of another semiconductor device 300.

Similar to the semiconductor device 200 in FIG. 2a, the semiconductor device 300 shown in FIG. 3 can also contain a semiconductor substrate 310 and a gate stack 305 that includes: a “base” layer which contains TiN, TaN, or a combination of TiN and TaN 315, a conductive layer that does not contain or is not entirely made of TiN, TaN, or a combination of TiN and TaN 320, and a tungsten layer 330. The gate stack 305 can also include other optional layers such as a first interfacial layer (not shown) overlaying the semiconductor substrate 310, a gate dielectric layer (not shown) overlaying the first interfacial layer, a second interfacial layer 325 that is between the conductive layer 320 and the tungsten layer 330, and an encapsulation layer (not shown) overlaying the tungsten layer.

The semiconductor substrate 310, the conductive layer 320, and the optional layers of the gate stack 305 can be made of the same materials and measure the same in thickness as the semiconductor substrate 210, the conductive layer 220, and the optional layers of the gate stack 205 described above. The base layer 315 and tungsten layer 330 can measure the same in thickness as the base layer 215 and tungsten layer 230 described above with reference to FIG. 2a. Like the base layer 215 described with reference to FIG. 2a, the base layer 315 is composed substantially of titanium and nitrogen and/or tantalum and nitrogen, respectively, but can optionally also include smaller amounts of other elements as described above.

Similar to the conductive layer 220 described above with reference to FIG. 2a, if the conductive layer 320 in FIG. 3 is made of TaAlN or TiAlN, then the conductive layer 325 should contain a sufficient aluminum content and appropriate nitrogen content to allow the tungsten layer 330 to form large grains, resulting in low resistivity. Accordingly, a sufficient aluminum content can be between about 5 and 40 atom % and preferably between about 10 and 35 atom %. An appropriate nitrogen content can be between about 10 and 50 atom %. For example, the conductive layer 320 can contain approximately 16% Al and approximately 30% N. If the conductive layer 320 is made of TaAlN or TiAlN and it contains a low aluminum content of approximately less than 15 atom %, it is particularly preferred for a surface oxidation process to be performed (to be discussed below.) The surface oxidation process can also be optionally performed if the conductive layer 320 contains a higher aluminum content. In addition, like the conductive layer 220 as described above, if the conductive layer 320 is made of other materials, then the conductive layer 320 or the semiconductor device 300 can be optionally subject to surface oxidation.

The optional encapsulation layer (not shown) of the gate stack 305 can also be partially or completely removed subsequently in processing, for example to make contact to the gate line.

The gate stack 305 can include spacers 350 of an insulating oxide or nitride compound, for example SiO₂, Si₃N₄, Al₂O₃, HfO₂, or ZrO₂, or of mixtures or multilayers thereof, where the spacers 350 most preferably are in direct contact with all layers of the gate stack 305. The encapsulation layer can be made of the same material as the spacers 350, or it can be made of a different material.

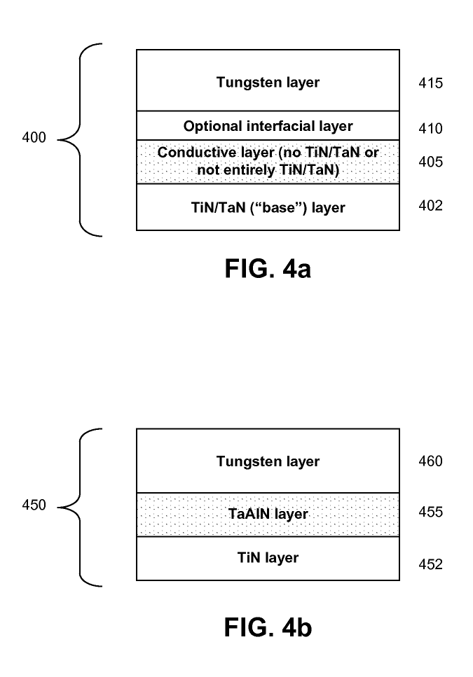

Referring to FIG. 4a, the illustration shows a cross sectional view of a layered structure 400 according to an embodiment of the present invention. The layered structure 400 includes: a “base” layer which contains TiN, TaN, or a combination of TiN and TaN 402, a conductive layer that does not contain or is not entirely made of TiN, TaN, or a combination of TiN and TaN 405, and a tungsten layer 415. The layered structure 400 can also include other optional layers such as an interfacial layer 410 that is between the conductive layer 405 and the tungsten layer 415.

The conductive layer 405 can be made of the same materials and measure the same thickness as the conductive layers 220 (FIGS. 2a) and 320 (FIG. 3.) The optional interfacial layer 410 can be made of the same materials and measure the same thickness as the optional interfacial layers 225 (FIGS. 2a) and 325 (FIG. 3). The base layer 405 and the tungsten layer 415 can measure the same in thickness as the base layers 215 (FIGS. 2a) and 315 (FIG. 3) and the tungsten layers 230 (FIGS. 2a) and 330 (FIG. 3). Additionally, the base layer 405 is composed substantially of titanium and nitrogen and/or tantalum and nitrogen, respectively, but can optionally also include smaller amounts of other elements as described above for the base layers 215 and 315 described with reference to FIG. 2a and FIG. 3.

Similar to the conductive layers 220 (FIGS. 2a) and 320 (FIG. 3), if the conductive layer 405 in FIG. 4a is made of TaAlN or TiAlN, then the conductive layer 405 should contain a sufficient aluminum content and appropriate nitrogen content to allow the tungsten layer 415 to form large grains, resulting in low resistivity. Accordingly, a sufficient aluminum content can be between about 5 and 40 atom % and preferably between about 10 and 35 atom %. An appropriate nitrogen content can be between about 10 and 50 atom %. For example, the conductive layer 405 can contain approximately 16% Al and approximately 30% N. If the conductive layer 405 is made of TaAlN or TiAlN and it contains a low aluminum content of approximately less than 15 atom %, it is particularly preferred for a surface oxidation process to be performed (to be discussed below.) The surface oxidation process can also be optionally performed if the conductive layer 405 contains a higher aluminum content. In addition, like the conductive layers 220 (FIGS. 2a) and 320 (FIG. 3), if the conductive layer 405 is made of other materials, then the conductive layer 405 or the device 400 can be optionally subject to surface oxidation.

Referring to FIG. 4b, the illustration shows a cross sectional view of an example layered structure 450 of FIG. 4a. In this example layered structure 450, a TaAlN conductive layer 455 overlays the TiN layer 452. A tungsten layer 460 overlays the TaAlN conductive layer 455.

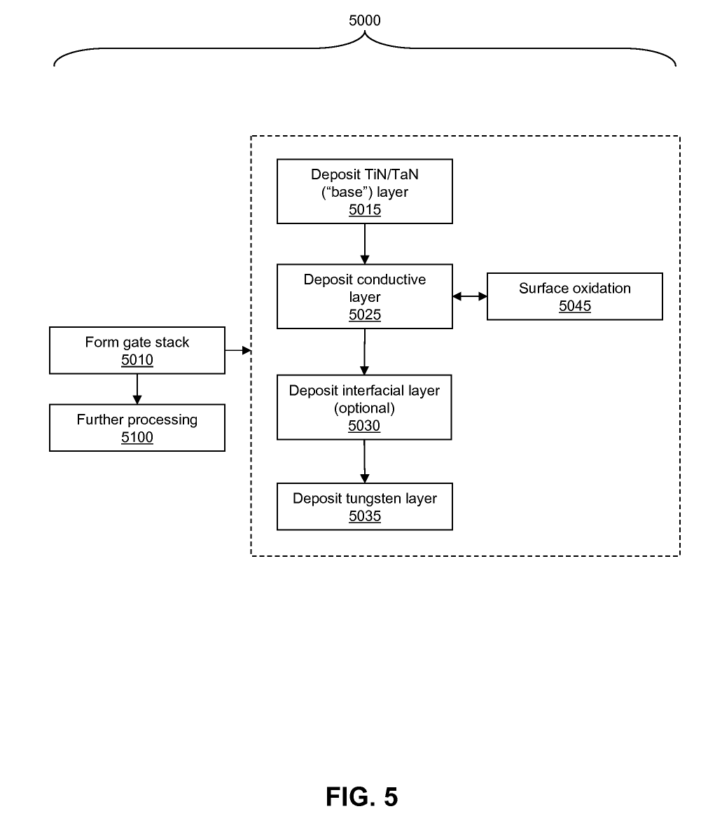

According to another embodiment of the present invention, a method is provided for fabricating a semiconductor device having a gate stack that includes an underlayer for a tungsten deposit. This underlayer can be a conductive layer that does not contain or is not entirely made of TiN, TaN, or a combination of TiN and TaN. The underlayer can also be a combination of an interfacial layer that overlays the conductive layer. Referring to FIG. 5, the illustration shows an overview of the method 5000 for fabricating the semiconductor device.

The method 5000 begins at step 5010. A gate stack is fabricated on a semiconductor substrate, as indicated in block 5010. The gate stack has a conductive layer as the underlayer for a tungsten deposit. The gate stack can be formed with layers of the same materials, measuring the same thickness as described for layers 215, 220, 225, 230, 315, 320, 325, 330 of the gate stacks 205, 305 in FIG. 2a and FIG. 3.

A first interfacial layer can be optionally grown on or deposited onto the semiconductor substrate (not shown in the figure). The first interfacial layer can be made of the same materials and measure the same in thickness as the first optional interfacial layers in the above-described embodiments of the present invention. Conventional deposition methods can be used to deposit the first interfacial layer onto the semiconductor substrate.

A gate dielectric layer can next be optionally deposited grown on or deposited onto the first interfacial layer or the semiconductor substrate, block 5020. The gate dielectric layer can be made of the same materials and measure the same in thickness as the gate dielectric layers in the above-described embodiments of the present invention. The gate dielectric layer can be grown or deposited by conventional methods such as, for example, rapid thermal oxidation, rapid thermal nitridation, rapid thermal oxynitridation, furnace oxidation, furnace nitridation, furnace oxynitridation, plasma oxidation, plasma nitridation, metal oxide chemical vapor deposition (MOCVD), sputtering or other physical vapor deposition (PVD) techniques, chemical vapor deposition (CVD), atomic layer deposition (ALD), or any combination of such techniques.

A “base” layer which contains TiN, TaN, or a combination of TiN and TaN can be deposited onto the semiconductor substrate, block 5015, or if a first interfacial layer, a gate dielectric layer, or other optional layers have been formed in the gate stack, the base layer can be deposited onto such optional layers. The base layer can measure the same in thickness as the base layers in the above-described embodiments of the present invention. Additionally, the base layer is composed substantially of titanium and nitrogen and/or tantalum and nitrogen, respectively, but can optionally also include smaller amounts of other elements as described above for the base layers described in the above embodiments. The base layer can be deposited by conventional methods such as, for example, sputtering or other physical vapor deposition (PVD) techniques, chemical vapor deposition (CVD), atomic layer deposition (ALD), or any combination of such techniques.

Next, the conductive layer can be deposited onto the base layer, block 5025. The conductive layer, which does not contain or is not entirely made of TiN, TaN, or a combination of TiN and TaN, can be made of the same materials and measure the same thickness as the conductive layers 220, 320, 405 described above with reference to FIG. 2a, FIG. 3, and FIG. 4a. The conductive layer can be deposited by conventional methods such as, for example, sputtering or other physical vapor deposition (PVD) techniques, chemical vapor deposition (CVD), atomic layer deposition (ALD), or any combination of such techniques

As mentioned above, if the conductive layer is made of TaAlN or TiAlN, then the conductive layer should contain a sufficient aluminum content and appropriate nitrogen content to allow for a tungsten layer to form large grains, resulting in low resistivity. Accordingly, a sufficient aluminum content can be between about 5 and 40 atom % and preferably between about 10 and 35 atom %. An appropriate nitrogen content can be between about 10 and 50 atom %. If the conductive layer is made of TaAlN or TiAlN and it contains a low aluminum content of approximately less than 15 atom %, it is particularly preferred for a surface oxidation process to be performed, block 5045. The surface oxidation process can also be optionally performed if the conductive layer contains a higher aluminum content, block 5045. If the conductive layer is made of other materials, then the conductive layer or the device can be optionally subject to surface oxidation, block 5045.

The surface oxidation process is a treatment of the surface with a substance or atmosphere which results in the incorporation of oxygen atoms in surface- or near-surface regions of the conductive layer. Examples of surface oxidation include, but are not limited to, air exposure, oxygen gas exposure, plasma oxidation, radical shower oxidation (ROX), water vapor exposure, or treatment with liquid water or with other oxygen-containing wet chemicals, either at room temperature or at a temperature below or above room temperature. Air exposure can just be exposure to room/lab air, by taking the device out of the processing chamber or by letting an air stream into the chamber. ROX is exposure to oxygen radicals.

Next, another interfacial layer can be optionally deposited onto the conductive layer, block 5030, before a tungsten layer is deposited at block 5035. Conventional methods can be used to deposit this optional interfacial layer.

The tungsten layer can be deposited onto the conductive layer, block 5035, or onto the optional interfacial layer described with reference to block 5030. Possible methods for depositing the tungsten layer include, but are not limited to, sputtering, physical vapor deposition, molecular beam deposition, atomic layer deposition, or chemical vapor deposition.

Thereafter, an encapsulation layer can be optionally deposited onto the tungsten layer using conventional methods (not shown in the figure). The encapsulation layer can be made of the same materials and measure the same in thickness as the encapsulation layers in the above-described embodiments of the present invention. As discussed earlier, the encapsulation layer can be partially or completely removed subsequently in processing to make contact to the gate line. For example, the encapsulation layer can be opened up in a subsequent step so as to make contact with the gate line.

Unless otherwise specified, the layers of the gate stack can be made by conventional deposition and patterning methods. Spacers, such as those described with reference to FIG. 3, can be added by conventional semiconductor processing techniques, such as, for example, rapid thermal chemical vapor deposition (RTCVD) or low-pressure chemical vapor deposition (LPCVD), atomic layer deposition (ALD), or any combination of such techniques. Thereafter, device processing continues to finish the semiconductor device, block 5100.

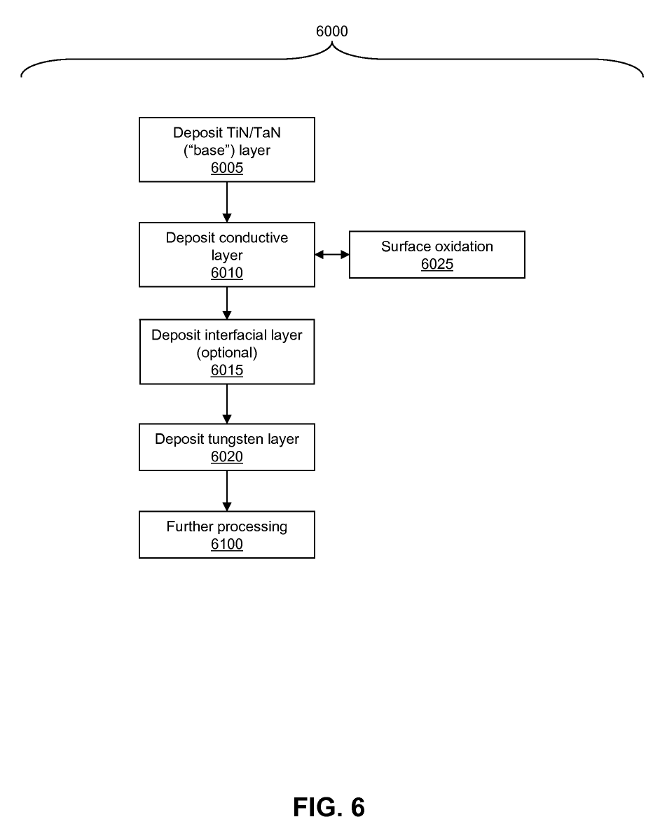

Some of the steps discussed with reference to FIG. 5 for fabricating the semiconductor device can also be performed to form a layered structure having a conductive layer as the underlayer for a tungsten deposit, where the conductive layer does not contain or is not entirely made of TiN, TaN, or a combination of TiN and TaN. Referring to FIG. 6, the illustration shows an overview of the method 6000 for fabricating the layered structure according to an embodiment of the present invention.

The method 6000 begins at step 6005, where a “base” layer containing TiN, TaN, or a combination of TiN and TaN is formed or deposited onto a surface. The base layer can measure the same in thickness as the base layers in the above-described embodiments of the present invention. Additionally, the base layer is composed substantially of titanium and nitrogen and/or tantalum and nitrogen, respectively, but can optionally also include smaller amounts of other elements as described above for the base layers described in the above embodiments. The base layer can be deposited by conventional methods such as, for example, sputtering or other physical vapor deposition (PVD) techniques, chemical vapor deposition (CVD), atomic layer deposition (ALD), or any combination of such techniques.

Next, a conductive layer can be deposited onto the base layer, block 6010. The conductive layer can be made of the same materials and measure the same thickness as the conductive layers 220, 320, 405 described above with reference to FIG. 2a, FIG. 3, and FIG. 4a. The conductive layer can be deposited by conventional methods such as, for example, sputtering or other physical vapor deposition (PVD) techniques, chemical vapor deposition (CVD), atomic layer deposition (ALD), or any combination of such techniques.

As mentioned above, if the conductive layer is made of TaAlN or TiAlN, then the conductive layer should contain a sufficient aluminum content and appropriate nitrogen content to allow for a tungsten layer to form large grains, resulting in low resistivity. Accordingly, a sufficient aluminum content can be between about 5 and 40 atom % and preferably between about 10 and 35 atom %. An appropriate nitrogen content can be between about 10 and 50 atom %. If the conductive layer is made of TaAlN or TiAlN and it contains a low aluminum content of approximately less than 15 atom %, it is particularly preferred for a surface oxidation process to be performed (described above), block 6025. The surface oxidation process can also be optionally performed if the conductive layer contains a higher aluminum content, block 6025. If the conductive layer is made of other materials, then the conductive layer or the device can be optionally subject to surface oxidation, block 6025.

An interfacial layer can be optionally deposited onto the conductive layer, block 6015, before a tungsten layer is deposited at block 6020. Conventional methods can be used to deposit the interfacial layer.

The tungsten layer can be deposited onto the optional interfacial layer or the conductive layer, block 6020. Possible methods for depositing the tungsten layer include, but are not limited to, sputtering, physical vapor deposition, molecular beam deposition, atomic layer deposition, or chemical vapor deposition.

Thereafter, device processing continues to finish the layered structure, block 6100.

It will be apparent to those skilled in the art having regard to this disclosure that other modifications of the present invention beyond those embodiments specifically described here can be made without departing from the spirit of the invention. For example, the semiconductor devices and layered structures described above can include additional optional layers and the methods for fabricating such devices and structures can include additional optional steps for depositing such layers. Accordingly, such modifications are considered within the scope of the present invention as limited solely by the appended claims.

1. A layered structure, comprising:
a base layer comprising a material selected from the group consisting of titanium nitride (TiN), tantalum nitride (TaN), and a combination thereof;
at least one conductive layers overlaying said base layer, wherein at least one of the conductive layers comprises a combination of first and second materials, wherein the first material is selected from the group consisting of: TiN, TaN, and a combination thereof, and the second material selected from the group consisting of: tantalum aluminum nitride (TaAlN), titanium aluminum nitride (TiAlN), tantalum silicon nitride (TaSiN), titanium silicon nitride (TiSiN), tantalum hafnium nitride (TaHfN), titanium hafnium nitride (TiHfN), hafnium nitride (HfN), hafnium carbide (HfC), tantalum carbide (TaC), vanadium nitride (VN), niobium nitride (NbN), and any combination thereof; and
a tungsten layer deposited above the at least one conductive layer.

2. The layered structure according to claim 1, further comprising:
an interfacial layer overlaying said conductive layer, wherein said interfacial layer comprises a material selected from the group consisting of: aluminum oxide (Al₂O₃), hafnium oxide (HfO₂), silicon dioxide (SiO₂), and a combination thereof.

3. The layered structure according to claim 1, wherein said conductive layer allows said tungsten layer to form large grains and to attain low resistivity.

4. The layered structure according to claim 1, wherein said second material comprises TaAlN and has an aluminum content sufficient to allow said tungsten layer to form large grains and to attain low resistivity

5. The layered structure according to claim 1, wherein said conductive layer or said device is subject to surface oxidation.

6. A semiconductor device comprising:
a semiconductor substrate;
a base layer comprising a material selected from the group consisting of titanium nitride (TiN), tantalum nitride (TaN), and a combination thereof, wherein said base layer overlays said semiconductor substrate;
at least one conductive layers overlaying said base layer, wherein at least one of the conductive layers comprises a combination of first and second materials, wherein the first material is selected from the group consisting of: TiN, TaN, and a combination thereof, and the second material selected from the group consisting of: tantalum aluminum nitride (TaAlN), titanium aluminum nitride (TiAlN), tantalum silicon nitride (TaSiN), titanium silicon nitride (TiSiN), tantalum hafnium nitride (TaHfN), titanium hafnium nitride (TiHfN), hafnium nitride (HfN), hafnium carbide (HfC), tantalum carbide (TaC), vanadium nitride (VN), niobium nitride (NbN), and any combination thereof; and a tungsten layer deposited above said conductive layer.

7. The device according to claim 6, further comprising:
an interfacial layer overlaying said conductive layer, wherein said interfacial layer comprises a material selected from the group consisting of: aluminum oxide (Al₂O₃), hafnium oxide (HfO₂), silicon dioxide (SiO₂), and a combination thereof.

8. The device according to claim 6, wherein said conductive layer allows said tungsten layer to form large grains and to attain low resistivity.

9. The device according to claim 6, wherein said conductive layer comprises TaAIN and said conductive layer has aluminum content sufficient to allow said tungsten layer to form large grains and to attain low resistivity.

10. The device according to claim 6, wherein said conductive layer or said device is subject to surface oxidation.

11. A method of fabricating a semiconductor device, said method comprising:
depositing a base layer on a semiconductor substrate, wherein said base layer comprises a material selected from the group consisting of: titanium nitride (TiN), tantalum nitride (TaN), and a combination thereof;
depositing at least one conductive layers overlaying said base layer, wherein at least one of the conductive layers comprises a combination of first and second materials, wherein the first material is selected from the group consisting of: TiN, TaN, and a combination thereof, and the second material selected from the group consisting of: tantalum aluminum nitride (TaAlN), titanium aluminum nitride (TiAlN), tantalum silicon nitride (TaSiN), titanium silicon nitride (TiSiN), tantalum hafnium nitride (TaHfN), titanium hafnium nitride (TiHfN), hafnium nitride (HfN), hafnium carbide (HfC), tantalum carbide (TaC), vanadium nitride (VN), niobium nitride (NbN), and any combination thereof; and depositing a tungsten layer above said conductive layer.

12. The method according to claim 11, further comprising depositing an interfacial layer on said conductive layer after depositing said conductive layer.

13. The method according to claim 12, wherein said interfacial layer comprises a material selected from the group consisting of: aluminum oxide (Al₂O₃), hafnium oxide (HfO₂), silicon dioxide (SiO₂), and a combination thereof.

14. The method according to claim 11, wherein depositing said conductive layer allows said tungsten layer to form large grains and to attain low resistivity.

15. The method according to claim 11, wherein said second material comprises TaAIN and has aluminum content sufficient to allow said tungsten layer to form large grains and to attain low resistivity.

16. The method according to claim 11, further comprising subjecting said conductive layer or said layered structure to a surface oxidation process before depositing said tungsten layer.

17. The method according to claim 16, wherein said surface oxidation process is air exposure or radical shower oxidation (ROX).
